(19) United States
(12) Patent Application Publication
(10) Pub. No.: US 2025/0393415 A1
(43) Pub. Date: Dec. 25, 2025

(54) DISPLAY DEVICE AND ELECTRONIC DEVICE INCLUDING THE SAME

(71) Applicant: Samsung Display Co., LTD., Yongin-si (KR)

(72) Inventors: YECHAN CHOI, Yongin-si (KR); Changwook KIM, Yongin-si (KR); MINJUNG ANN, Yongin-si (KR); Jun Hee LEE, Yongin-si (KR); Hyun Duck CHO, Yongin-si (KR); Kook Hyun CHOI, Yongin-si (KR); Beohm Rock CHOI, Yongin-si (KR)

(73) Assignee: Samsung Display Co., LTD., Yongin-si (KR)

(21) Appl. No.: 19/061,416

(22) Filed: Feb. 24, 2025

(30) Foreign Application Priority Data
Jun. 25, 2024 (KR) 10-2024-0083192

(51) Int. Cl. H10K 59/126; H10K 59/122; H10K 59/80; H10K 102/00

(52) U.S. Cl. CPC H10K 59/126; H10K 59/122; H10K 59/8791; H10K 2102/351

(57) ABSTRACT

A display device includes: a substrate; a first electrode disposed on the substrate; a pixel defining layer having a pixel opening disposed on the first electrode; a light emitting layer disposed in the pixel opening; a second electrode disposed on the light emitting layer; an encapsulation layer disposed on the second electrode; and a light blocking member disposed on the encapsulation layer, overlapping the pixel defining layer, and having a light blocking member opening, wherein an entire upper surface of the pixel defining layer overlaps the light blocking member, and at least a portion of a side surface of the pixel defining layer overlaps the light blocking member opening.

### CROSS-REFERENCE TO RELATED APPLICATION

This application claims priority to and benefits of Korean Patent Application No. 10-2024-0083192 under 35 U.S.C. § 119, filed on Jun. 25, 2024 in the Korean Intellectual Property Office, the entire contents of which are incorporated herein by reference.

### BACKGROUND

### 1. Technical Field

Embodiments relate to a display device and an electronic device including the display device.

### 2. Description of the Related Art

A display device is a device for displaying an image, and includes a liquid crystal display (LCD), an organic light emitting diode (OLED) display, and the like. The display device is used in various electronic devices such as mobile phones, navigation devices, digital cameras, electronic books, portable game machines, and various terminals.

A display device such as an organic light emitting display device may have a structure that can be bent or folded by using a flexible substrate.

In small electronic devices such as mobile phones, optical elements such as camera sensors and optical sensors are formed in a bezel area around a display area, but as a size of the display area is increased while a size of a peripheral area of the display area gradually decreases, technologies are being developed that allow cameras or optical sensors to be disposed on a rear surface of the display area.

### SUMMARY

Embodiments are intended to provide a display device capable of reducing or minimizing a reflected diffraction pattern that occurs in case that external light is reflected.

However, embodiments are not limited to those set forth herein. The above and other embodiments will become more apparent to one of ordinary skill in the art to which the disclosure pertains by referencing the detailed description of the disclosure given below.

An embodiment provides a display device including: a substrate; a first electrode disposed on the substrate; a pixel defining layer having a pixel opening disposed on the first electrode; a light emitting layer disposed in the pixel opening; a second electrode disposed on the light emitting layer; an encapsulation layer disposed on the second electrode; and a light blocking member disposed on the encapsulation layer, overlapping the pixel defining layer, and having a light blocking member opening, wherein an entire upper surface of the pixel defining layer overlaps the light blocking member, and at least a portion of a side surface of the pixel defining layer overlaps the light blocking member opening.

A contact line where the upper surface and the side surface of the pixel defining layer meet may overlap the light blocking member.

At least a portion of the side surface of the pixel defining layer may overlap the light blocking member.

A separation distance (P) that is a minimum planar distance between an edge portion of the side surface of the pixel defining layer and an edge portion of the light blocking member, a margin distance (Margin) that is a minimum planar distance between an edge portion of the upper surface of the pixel defining layer and an edge portion of the light blocking member, an inclination angle (θ) that is an angle formed by the side surface of the pixel defining layer and the upper surface of the first electrode, and a thickness (h) that is a vertical distance in a cross-sectional view between the upper surface of the pixel defining layer and the upper surface of the first electrode may be in a relationship as follows.

$$tan θ = \frac{h}{Pullback + Margin}$$

The separation distance may be in a range of about 4 μm to about 6 μm, and the margin distance may be greater than about 0 and less than or equal to about 2 μm.

The inclination angle may be in a range of about 20.5° to about 30°.

The thickness may be in a range of about 2 μm to about 4 μm.

The display device may further include a color filter disposed between adjacent light blocking members.

The display device may further include a window layer disposed on the light blocking member and the color filter.

Another embodiment provides a display device including: a substrate; a first electrode disposed on the substrate; a first pixel defining layer having a first pixel opening and a second pixel defining layer having a second pixel opening, wherein the first pixel opening and the second pixel opening are disposed on the first electrode; a first light emitting layer disposed in the first pixel opening; a second light emitting layer disposed in the second pixel opening; a second electrode disposed on the first light emitting layer and the second light emitting layer; an encapsulation layer disposed on the second electrode; and a light blocking member disposed on the encapsulation layer, overlapping the first pixel defining layer and the second pixel defining layer, and having a light blocking member opening, wherein the first pixel defining layer includes a first upper surface and a first side surface, the entire first upper surface overlaps the light blocking member and at least a portion of the first side surface overlaps the light blocking member opening, the second pixel defining layer includes a second upper surface and a second side surface, and at least a portion of the second upper surface overlaps the light blocking member opening.

The second side surface of the second pixel defining layer may be spaced apart from the light blocking member in a plan view.

A first contact line where the first upper surface and the first side surface meet may overlap the light blocking member, and a second contact line where the second upper surface and the second side surface meet may overlap the light blocking member opening.

The first light emitting layer and the second light emitting layer may emit light of different colors.

Another embodiment provides a display device including: a substrate; a first electrode disposed on the substrate; a pixel defining layer having a pixel opening disposed on the first electrode; a light emitting layer disposed in the pixel opening; a second electrode disposed on the light emitting layer; an encapsulation layer disposed on the second electrode; a first color filter disposed on the encapsulation layer and overlapping the pixel defining layer and the light emitting layer; and a second color filter and a third color filter disposed on the encapsulation layer, overlapping the pixel defining layer, and spaced apart from the light emitting layer, wherein an entire contact line where the upper surface and the side surface of the pixel defining layer meet overlaps the second color filter and the third color filter.

An edge portion of the side surface of the pixel defining layer may overlap the first color filter and may be spaced apart from the second color filter and the third color filter.

The entire upper surface of the pixel defining layer may overlap the second color filter and the third color filter.

The entire third color filter may overlap the second color filter, and the entire contact line may overlap the third color filter.

The entire upper surface of the pixel defining layer may overlap the third color filter.

The side surface of the pixel defining layer and an upper surface of the first electrode may form an inclination angle greater than 0° and less than 90°.

The inclination angle may be in a range of about 20.5° to about 30°.

Another embodiment provides an electronic device may include: a display device including: a substrate; a first electrode disposed on the substrate; a pixel defining layer having a pixel opening disposed on the first electrode; a light emitting layer disposed in the pixel opening; a second electrode disposed on the light emitting layer; an encapsulation layer disposed on the second electrode; a first color filter disposed on the encapsulation layer and overlapping the pixel defining layer and the light emitting layer; and a second color filter and a third color filter disposed on the encapsulation layer, overlapping the pixel defining layer, and spaced apart from the light emitting layer, wherein an entire contact line where an upper surface and a side surface of the pixel defining layer meet may overlap the second color filter and the third color filter.

A contact line where the upper surface and the side surface of the pixel defining layer meet may overlap the light blocking member.

At least a portion of the side surface of the pixel defining layer may overlap the light blocking member.

A separation distance (Pullback) that is a minimum planar distance between an edge portion of the side surface of the pixel defining layer and an edge portion of the light blocking member, a margin distance (Margin) that is a minimum planar distance between an edge portion of the upper surface of the pixel defining layer and an edge portion of the light blocking member, an inclination angle (θ) that is an angle formed by the side surface of the pixel defining layer and the upper surface of the first electrode, and a thickness (h) that is a vertical distance in a cross-sectional view between the upper surface of the pixel defining layer and the upper surface of the first electrode may be in a relationship as follows.

$$tan θ = \frac{h}{Pullback + Margin}$$

The separation distance may be in a range of about 4 μm to about 6 μm, and the margin distance may be greater than about 0 and less than or equal to about 2 μm.

The electronic device may be at least one of an organic light-emitting display apparatus, an inorganic light-emitting display apparatus, a quantum dot light-emitting display apparatus, display screens of portable electronic apparatus, such as mobile phones, smartphones, tablet personal computers (PCs), mobile communication terminals, electronic notebooks, electronic books, portable multimedia players (PMPs), navigation devices, and ultra mobile PCs (UMPCs), display screens of televisions, notebooks, monitors, advertisement panels, Internet of things (IoT) devices, a portable communication device a smartphone, a computer device, a portable multimedia device, a portable medical device, a camera, a wearable device, and a home appliance.

According to the embodiments, it is possible to provide a display device capable of reducing or minimizing a reflected diffraction pattern that occurs in case that external light is reflected.

### BRIEF DESCRIPTION OF THE DRAWINGS

FIG. 1 is a schematic perspective view of a state of use of a display device according to an embodiment.

FIG. 2 is an exploded schematic perspective view of a display device according to an embodiment.

FIG. 3 is a schematic block diagram of a display device according to an embodiment.

FIG. 4 is a schematic plan view of pixels in a display area of a display device according to an embodiment.

FIG. 5 is a schematic plan view of a shape of a unit pixel in a display area of a display device according to an embodiment.

FIG. 6 is a schematic cross-sectional view taken along line A-A′ of FIG. 5.

FIG. 7 is a schematic cross-sectional view of a portion of a display area shown in FIG. 6.

FIG. 8 is a schematic plan view of a shape of a unit pixel of a display device according to a comparative example.

FIG. 9 is a schematic cross-sectional view taken along line B-B′ of FIG. 8.

FIG. 10 is an image of reflection characteristics of a display device according to an embodiment.

FIG. 11 is an image of reflection characteristics of a display device according to a comparative example.

FIG. 12 to FIG. 14 are schematic plan views of a unit pixel in a display area of a display device according to another embodiment.

FIG. 15 is a schematic cross-sectional view of a portion of a display area of a display device according to another embodiment.

FIGS. 16 and 17 are schematic perspective views illustrating application examples of electronic devices.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z—axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

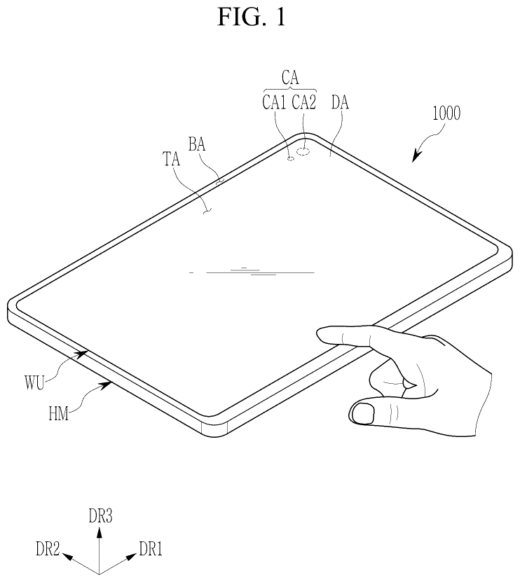

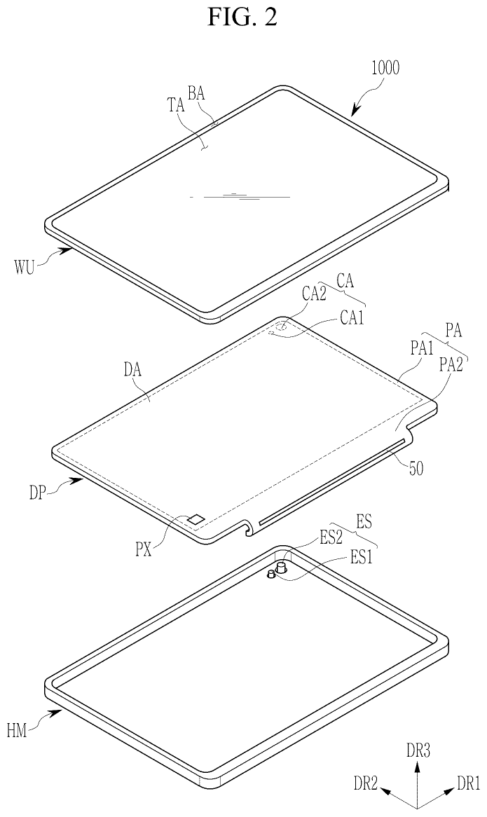

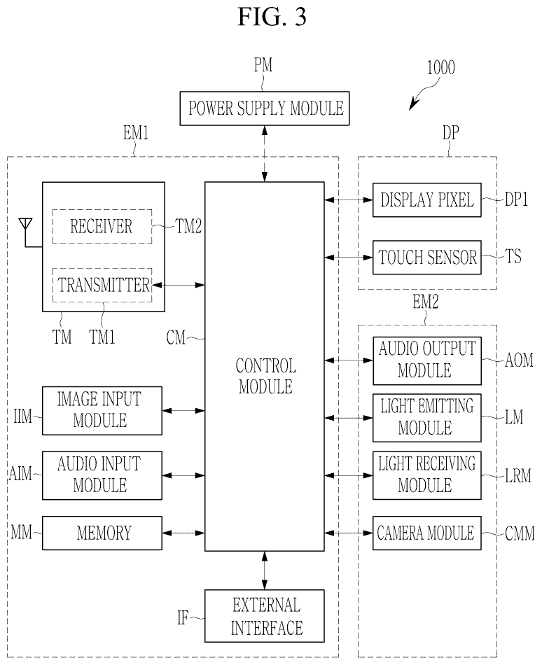

FIG. 1 is a schematic perspective view of an operation state of a display device according to an embodiment, FIG. 2 is an exploded schematic perspective view of a display device according to an embodiment, and FIG. 3 is a schematic block diagram of a display device according to an embodiment.

Referring to FIG. 1, a display device 1000 according to an embodiment may be a device for displaying a moving image or a still image, and may be used as a display screen of a portable electronic device such as a mobile phone, a smart phone, a tablet personal computer (PC), a mobile communication terminal, an electronic notebook, an electronic book, a portable multimedia player (PMP), a navigation device, and an ultramobile PC (UMPC), and may be used as a display screen of various products such as a television set, a laptop computer, a monitor, a billboard, the Internet of things (IoT). For example, the display device 1000 according to an embodiment may be used in a wearable device such as a smart watch, a watch phone, a glasses display, and a head mounted display (HMD). For example, the display device 1000 according to an embodiment may be used as an instrument panel of a vehicle, a center information display (CID) disposed on a center fascia or dashboard of a vehicle, a room mirror display that replaces a side mirror of a vehicle, and a display disposed on the back of a front seat for entertainment for a rear seat of a vehicle. For better comprehension and descriptive convenience, FIG. 1 illustrates a case in which the display device 1000 is used for a tablet PC.

The display device 1000 may display an image toward a third direction DR3 on a display surface parallel to each of a first direction DR1 and a second direction DR2. A display surface on which an image is displayed may correspond to a front surface of the display device 1000, and may correspond to a front surface of a cover window WU. An image may include a static image as well as a dynamic image.

In an embodiment, a front (or top) surface and a rear (or bottom) surface of each member are defined based on a direction in which an image is displayed. The front and rear surfaces may be opposite to each other in the third direction DR3, and a normal direction of each of the front and rear surfaces may be parallel to the third direction DR3. A separation distance in the third direction DR3 between the front and rear surfaces may correspond to a thickness of a display panel in the third direction DR3.

The display device 1000 according to an embodiment may detect a user's input (see hand of FIG. 1) applied from the outside. The user's input may include various types of external inputs such as a part of the user's body, light, heat, or pressure. In an embodiment, the user's input is shown to be the user's hand applied to the front surface. However, embodiments are not limited thereto. The user's input may be provided in various forms. For example, the display device 1000 may sense the user's input applied to the lateral or rear surface of the display device 1000 according to the structure of the display device 1000.

Referring to FIG. 1 and FIG. 2, the display device 1000 may include a cover window WU, a housing HM, a display panel DP, and an optical element ES. In an embodiment, the cover window WU and the housing HM may be combined to form an appearance of the display device 1000.

The cover window WU may include an insulating panel. For example, the cover window WU may be made of glass, plastic, or a combination thereof.

A front surface of the cover window WU may define the front surface of the display device 1000. A transmission area TA may be an optically transparent area. For example, the transmission area TA may be an area having visible light transmittance of about 90% or more.

A blocking area BA may define a shape of the transmission area TA. The blocking area BA may be adjacent to the transmission area TA, and may surround the transmission area TA. The blocking area BA may be an area having relatively low light transmittance compared with the transmission area TA. The blocking area BA may include an opaque material that blocks light. The blocking area BA may have a selected color. The blocking area BA may be defined by a bezel layer provided separately from a transparent substrate defining the transmission area TA, or may be defined by an ink layer formed by being inserted into or coloring the transparent substrate.

The display panel DP may include a front surface that includes a display area DA and a non-display area PA. The display area DA may be an area in which a pixel operates to emit light according to an electrical signal. The non-display area PA of the display panel DP may include a driver 50.

In an embodiment, the display area DA may be an area that includes a pixel and in which an image is displayed, and may be an area in which a touch sensor is disposed at an upper side of the pixel in the third direction DR3 to sense an external input.

The transmission area TA of the cover window WU may at least partially overlap the display area DA of the display panel DP. For example, the transmission area TA may overlap the front surface of the display area DA, or may overlap at least a portion of the display area DA. Accordingly, a user may view an image through the transmission area TA, or may provide an external input based on the image. However, embodiments are not limited thereto. For example, the display area DA may be divided into an area in which an image is displayed and an area in which an external input is sensed.

The non-display area PA of the display panel DP may at least partially overlap the blocking area BA of the cover window WU. The non-display area PA may be an area covered by the blocking area BA. The non-display area PA may be adjacent to the display area DA, and may surround the display area DA. Any image may not be displayed in the non-display area PA, and a driving circuit or driving wire for driving the display area DA may be disposed therein. The non-display area PA may include a first peripheral area PA1 disposed outside the display area DA and a second peripheral area PA2 including the driver 50, a connection wire, and a bending area. In an embodiment of FIG. 2, the first peripheral area PA1 may be disposed on three sides of the display area DA, and the second peripheral area PA2 may be disposed on the other side of the display area DA.

In an embodiment, the display panel DP may be assembled in a flat state in which the display area DA and the non-display area PA facing the cover window WU. However, embodiments are not limited thereto. A portion of the non-display area PA of the display panel DP may be bent. For example, a portion of the non-display area PA faces the rear surface of the display device 1000, so that the blocking area BA shown on the front surface of the display device 1000 may be reduced, and in FIG. 2, the second peripheral area PA2 may be bent, so that it may be assembled after disposing it on the rear surface of the display area DA.

For example, the display panel DP may include a component area CA, e.g., a first component area CA1 and a second component area CA2. The first component area CAL and the second component area CA2 may be at least partially surrounded by the display area DA. The first component area CAL and the second component area CA2 are illustrated as being spaced apart from each other, but embodiments are not limited thereto, and may be partially connected. The first component area CA1 and the second component area CA2 may be areas in which a component using infrared light, visible light, or sound is disposed thereunder.

Light emitting diodes, and pixel circuits that generate and transmit light emitting current to each of the light emitting diodes are formed in the display area DA. For example, one light emitting diode and one pixel circuit portion are referred to as a pixel PX. One pixel circuit portion and one light emitting diode are formed in a one-to-one ratio in the display area DA.

The first component area CA1 may include a transmitter through which light and/or sound are transmitted and a display portion including pixels. The transmitter may be disposed between adjacent pixels, and may be formed of a layer through which light or/and sound are transmitted. The transmitter may be disposed between adjacent pixels, and in some embodiments, a layer that does not transmit light, such as a light blocking member, may overlap the first component area CA1. The number of pixels (hereinafter also referred to as resolution) per unit area of the pixels (hereinafter also referred to as normal pixels) included in the display area DA may be the same as the number of pixels per unit area of the pixels (hereinafter also referred to as first component pixels) included in the first component area CA1.

The second component area CA2 may include an area (hereinafter also referred to as light transmission area) formed of a transparent layer to allow light to pass through. For example, the light transmission area may include an opening, in which a conductive layer or a semiconductor layer is not disposed. For example, the light transmission area may include a layer that does not include a light blocking material, and a pixel defining layer and/or a light blocking member including the opening overlapping a position corresponding to the second component area CA2. Thus, the light transmission area may have a structure that does not block light. The number of pixels per unit area of the pixels (hereinafter also referred to as second component pixels) included in the second component area CA2 may be smaller than the number of pixels per unit area of the normal pixels included in the display area DA. Thus, the resolution of the second component pixel may be lower than that of the normal pixel.

Referring to FIG. 3 together with FIG. 1 and FIG. 2, the display panel DP may include the display area DA including a display pixel DP1, and a touch sensor TS. The display panel DP may be viewed by a user from the outside through the transmission area TA, by including the pixel, which is a component that displays an image. For example, the touch sensor TS may be disposed on the pixel, and may sense an external input applied from the outside. The touch sensor TS may sense an external input provided to the cover window WU.

Referring back to FIG. 2, the second peripheral area PA2 may include a bending portion. The display area DA and the first peripheral area PA1 may be in a flat state substantially parallel to a plane defined by the first direction DR1 and the second direction DR2, and one side of the second peripheral area PA2 may extend from being in a flat state through the bending part to being in a flat state again. At least a portion of the second peripheral area PA2 may be bent to be assembled to be disposed on the rear surface side of the display area DA. Since at least a portion of the second peripheral area PA2 overlaps the display area DA in a plan view when assembled, the blocking area BA of the display device 1000 may be reduced. However, embodiments are not limited thereto. For example, the second peripheral area PA2 may not be bent.

The driver 50 may be mounted on the second peripheral area PA2, and may be mounted on the bending portion or disposed on at least one of sides of the bending portion. The driver 50 may be provided in the form of a chip.

The driver 50 may be electrically connected to the display area DA to transmit an electrical signal to the display area DA. For example, the driver 50 may provide data signals to the pixels PX disposed in the display area DA. In another example, the driver 50 may include a touch driving circuit, and may be electrically connected to the touch sensor TS disposed in the display area DA. For example, the driver 50 may include various circuits in addition to the above-described circuits, or may be designed to provide various electrical signals to the display area DA.

For example, a pad portion may be disposed at an end portion of the second peripheral area PA2, and the display device 1000 may be electrically connected to a flexible printed circuit board (FPCB) including a driving chip by the pad portion. For example, the driving chip positioned on the flexible printed circuit board may include various driving circuits for driving the display device 1000 or connectors for supplying power. In some embodiments, instead of the flexible printed circuit board, a rigid printed circuit board (PCB) may be used.

The optical element ES may be disposed under the display panel DP. The optical element ES may include a first optical element ES1 overlapping the first component area CA1 and a second optical element ES2 overlapping the second component area CA2.

The first optical element ES1 may be an electronic element using light or sound. For example, the first optical element ES1 may be a sensor that receives and uses light such as an infrared sensor, a sensor that outputs and detects light or sound to measure a distance or recognize a fingerprint, a small lamp that outputs light, a speaker that outputs sound, and the like. In a case of an electronic element using light, light of various wavelength bands such as visible light, infrared light, and ultraviolet light may be used.

The second optical element ES2 may be at least one of a camera, an infrared camera (IR camera), a dot projector, an infrared illuminator, and a time-of-flight sensor (ToF sensor).

Referring to FIG. 3, the display device 1000 may include the display panel DP, a power supply module PM, a first electronic module EM1, and second electronic module EM2. The display panel DP, the power supply module PM, the first electronic module EM1, and the second electronic module EM2 may be electrically connected to each other. As an example, FIG. 3 illustrates the display pixel DP1 and the touch sensor TS disposed in the display area of the display panel DP.

The power supply module PM may supply power required for overall operation of the display device 1000. The power supply module PM may include a typical battery module.

The first electronic module EM1 and the second electronic module EM2 may include various functional modules for operating the display device 1000. The first electronic module EM1 may be mounted (e.g., directly mounted) on a motherboard electrically connected to the display panel DP, or mounted on a separate substrate to be electrically connected to the motherboard through a connector.

The first electronic module EM1 may include a control module CM, a wireless communication module TM, an image input module IIM, an audio input module AIM, a memory MM, and an external interface IF. Some of the modules may not be mounted on the motherboard, but may be electrically connected to the motherboard through the flexible printed circuit board connected thereto.

The control module CM may control the overall operation of the display device 1000. The control module CM may be a microprocessor. For example, the control module CM may activate or deactivate the display panel DP. The control module CM may control other modules such as the image input module IIM or the audio input module AIM based on a touch signal received from the display panel DP.

The wireless communication module TM may transmit/receive a wireless signal with another terminal by using a Bluetooth or Wi-Fi line. The wireless communication module TM may transmit/receive a voice signal by using a general communication line. The wireless communication module TM may include a transmitter TM1 that modulates and transmits a signal to be transmitted, and a receiver TM2 that demodulates a received signal.

The image input module IIM may process an image signal to convert the image signal into image data, which are displayed on the display panel DP. The audio input module AIM may receive an external audio signal input by a microphone in a recording mode, a voice recognition mode, and the like to convert it into electrical voice data.

The external interface IF may function as an interface connected to an external charger, a wired/wireless data port, a card socket (for example, a memory card, a SIM/UIM card), and the like.

The second electronic module EM2 may include an audio output module AOM, a light emitting module LM, a light receiving module LRM, and a camera module CMM, and at least some of them may be the optical elements ES and may be positioned on the rear surface of the display panel DP as shown in FIG. 2. The optical element ES may include the light emitting module LM, the light receiving module LRM, and the camera module CMM. For example, the second electronic module EM2 may be mounted (e.g., directly mounted) on the motherboard, mounted on a separate substrate to be electrically connected to the display panel DP through a connector, or electrically connected to the first electronic module EM1.

The audio output module AOM may convert audio data received from the wireless communication module TM or audio data stored in the memory MM to output the audio data to the outside.

The light emitting module LM may generate and output light. The light emitting module LM may output infrared rays. For example, the light emitting module LM may include an LED element. For example, the light receiving module LRM may detect or sense infrared rays. The light receiving module LRM may be activated in case that infrared rays of a selected level or more are sensed. The light receiving module LRM may include a CMOS (complementary metal-oxide-semiconductor) sensor. After the infrared light generated by the light emitting module LM is output, the infrared light may be reflected by an external subject (for example, a user's finger or face), and then the reflected infrared light may be incident on the light receiving module LRM. The camera module CMM may capture an external image.

In an embodiment, the optical element ES may additionally include a light sensing sensor or a thermal sensing sensor. The optical element ES may sense an external object received through the front surface thereof, or may provide a sound signal such as a voice through the front surface to the outside. For example, the optical element ES may include constituent elements, and is not limited to any one embodiment.

Referring back to FIG. 2, the housing HM may be combined with the cover window WU. The cover window WU may be disposed on the front surface of the housing HM. The housing HM may be combined with the cover window WU to provide a selected accommodation space. The display panel DP and the optical element ES may be accommodated in the selected accommodation space disposed between the housing HM and the cover window WU.

The housing HM may include a material with relatively high rigidity. For example, the housing HM may include frames and/or plates made of glass, plastic, or metal, or a combination thereof. The housing HM may stably protect the components of the display device 1000 accommodated in an inner space thereof from external impact.

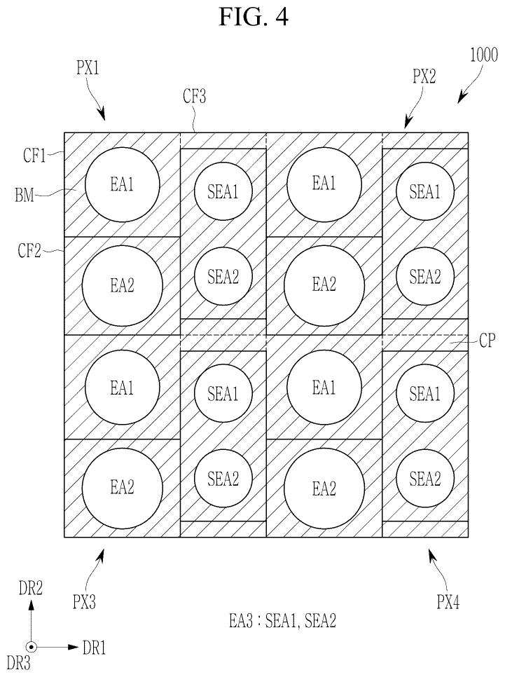

FIG. 4 is a schematic plan view of pixels in a display area of a display device according to an embodiment.

Referring to FIG. 4, the display device 1000 may include unit pixels PX1, PX2, PX3, and PX4 disposed in the display area DA and light emitting areas EA1, EA2, and EA3 disposed in each of the unit pixels PX1, PX2, PX3, and PX4. The unit pixels PX1, PX2, PX3, and PX4 may include the light emitting areas EA1, EA2, and EA3 displaying different colors, and may be disposed along the first direction DR1 and the second direction DR2. The first unit pixel PX1 and the second unit pixel PX2 may be adjacent to each other in the first direction DR1, and the first unit pixel PX1 and the third unit pixel PX3 may be adjacent to each other in the second direction DR2. The third unit pixel PX3 and the fourth unit pixel PX4 may be adjacent to each other in the first direction DR1, and the second unit pixel PX2 and the fourth unit pixel PX4 may be adjacent to each other in the second direction DR2. However, the disposition of the unit pixels PX1, PX2, PX3, and PX4 may be variously changed. For example, the unit pixels PX1, PX2, PX3, and PX4 may be disposed as a PenTile™ type or a diamond PenTile™ type.

The light emitting areas EA1, EA2, and EA3 of each of the unit pixels PX1, PX2, PX3, and PX4 may include a first light emitting area EA1, a second light emitting area EA2, and a third light emitting area EA3 that emit light of different colors. The third light emitting area EA3 may include a first sub-light emitting area SEA1 and a second sub-light emitting area SEA2 spaced apart from each other in the second direction DR2. The first sub-light emitting area SEA1 and the second sub-light emitting area SEA2 may be separated, but they may emit light of the same color to form a single third light emitting area EA3.

Each of the first light emitting area EA1, the second light emitting area EA2, and the third light emitting area EA3 may emit light of one of red, green, and blue colors. For example, the first light emitting area EA1 may emit red light, the second light emitting area EA2 may emit green light, and the third light emitting area EA3 may emit blue light. As another example, the first light emitting area EA1 may emit red light, the second light emitting area EA2 may emit blue light, and the third light emitting area EA3 may emit green light.

Each of the first light emitting area EA1, the second light emitting area EA2, the first sub-light emitting area SEA1, and the second sub-light emitting area SEA2 may have a circular planar shape, and may have an elliptical shape or a planar shape that approximates a circle. The light emitting areas EA1, EA2, and EA3 may have a planar shape without an angled portion, so that reflection characteristics may be improved.

In each of the unit pixels PX1, PX2, PX3, and PX4, the light emitting areas EA1, EA2, and EA3 may be disposed along the first direction DR1 and the second direction DR2. For example, as shown, the first light emitting area EA1 and the second light emitting area EA2 may be disposed to be spaced apart from each other in the second direction DR2. The third light emitting area EA3 may be disposed to be spaced apart from the first and second light emitting areas EA1 and EA2 in the first direction DR1. Throughout the display area, the first light emitting area EA1 and the second light emitting area EA2 may be alternately disposed along the second direction DR2, and the first sub-light emitting area SEA1 and the second sub-light emitting area SEA2 may be alternately disposed along the second direction DR2. The disposition of the light emitting areas EA1, EA2, and EA3 may be variously changed. For example, the light emitting areas EA1, EA2, and EA3 may be disposed as a PenTile™ type or a diamond PenTile™ type. Color patterns CP may be disposed on sides (e.g., opposite sides) of the third emission area EA3 in the second direction DR2. The color pattern CP may be a portion of the first color filter CF1 protruding in the first direction DR1.

Throughout the display area, a light blocking member BM may be disposed to be spaced apart from the light emitting areas EA1, EA2, and EA3.

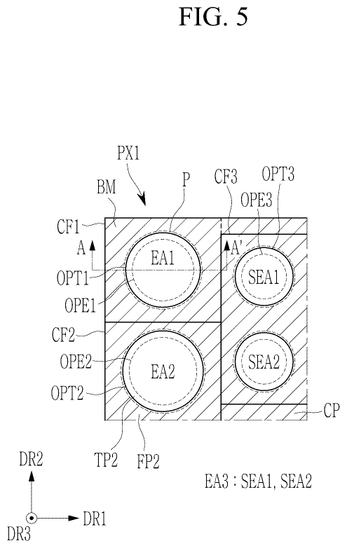

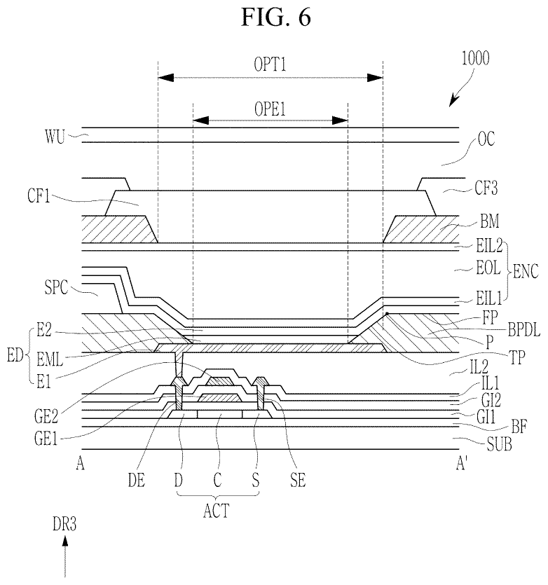

Hereinafter, a structure of a unit pixel in a display area of a display device according to an embodiment will be described with reference to FIG. 5 and FIG. 6. FIG. 5 is a schematic plan view of a shape of the first unit pixel PX1 among the pixels shown in FIG. 4. FIG. 6 is a schematic cross-sectional view taken along line A-A′ of FIG. 5.

Referring to FIG. 5 and FIG. 6, each of the light emitting areas EA1, EA2, and EA3 may be defined by pixel openings OPE1, OPE2, and OPE3 formed in a pixel defining layer BPDL of a light emitting element ED. For example, the first light emitting area EA1 may be defined by the first pixel opening OPE1, the second light emitting area EA2 may be defined by the second pixel opening OPE2, and the third light emitting area EA3 may be defined by the third pixel opening OPE3. Areas or sizes of the light emitting areas EA1, EA2, and EA3 may be different from each other. Referring to FIG. 5, an area of the second light emitting area EA2 may be larger than that of the first light emitting area EA1, and an area of the second light emitting area EA2 may be larger than that of each of the sub-light emitting areas SEA1 and SEA2. An area of the first sub-light emitting area SEA1 and an area of the second sub-light emitting area SEA2 may be the same as each other. Areas of the light emitting areas EA1, EA2, and EA3 may vary according to sizes of the pixel openings OPE1, OPE2, and OPE3 of the pixel defining layer BPDL. The amount of light emitted from the corresponding light emitting areas EA1, EA2, and EA3 may vary according to the areas of the light emitting areas EA1, EA2, and EA3, and the color of the image displayed on the display device 1000 may be controlled by adjusting the areas of the light emitting areas EA1, EA2, and EA3. The areas of the light emitting areas EA1, EA2, and EA3 may be related to the light efficiency, the lifespan of the light emitting element ED, and the like, and may be in a trade-off relationship with reflection by external light. The areas of the light emitting areas EA1, EA2, and EA3 may be adjusted in consideration of the above descriptions. The areas of light emitting areas EA1, EA2, and EA3 of the display device 1000 may be designed so that the reflected light of external light may be visually recognized as white mixed light.

The display device 1000 may include color filters CF1, CF2, and CF3 disposed on the light emitting areas EA1, EA2, and EA3. The color filters CF1, CF2, and CF3 may be disposed corresponding to the light emitting areas EA1, EA2, and EA3 or the pixel openings OPE1, OPE2, and OPE3. The color filters CF1, CF2, and CF3 may include a first color filter CF1 overlapping the first light emitting area EA1, a second color filter CF2 overlapping the second light emitting area EA2, and a third color filter CF3 overlapping the third light emitting area EA3. Each of the color filters CF1, CF2, and CF3 may have a larger area than the pixel openings OPE1, OPE2, and OPE3 of the pixel defining layer BPDL. The color filters CF1, CF2, and CF3 may include a colorant such as a dye or pigment that absorbs light of a wavelength band other than light of a specific wavelength band, and may be disposed corresponding to the color of light emitted from the light emitting areas EA1, EA2, and EA3. For example, the first color filter CF1 may be a red color filter that transmits only red light, the second color filter CF2 may be a green color filter that transmits only green light, and the third color filter CF3 may be a blue color filter that transmits only blue light.

Similar to the disposition of the light emitting areas EA1, EA2, and EA3, the color filters CF1, CF2, and CF3 may be disposed along the first direction DR1 and the second direction DR2. For example, the first color filter CF1 and the second color filter CF2 may be disposed adjacent to each other in the second direction DR2, and the third color filter CF3 may be disposed adjacent to the first color filter CF1 and the second color filter CF2 in the first direction DR1.

The areas of the light emitting areas EA1, EA2, and EA3 may be different from each other, and the areas of the color filters CF1, CF2, and CF3 may be different from each other. The light emitting areas EA1, EA2, and EA3 may have areas according to a specific ratio, and the color filters CF1, CF2, and CF3 also may have areas according to a specific ratio. However, the area ratio between the light emitting areas EA1, EA2 and EA3 and the area ratio between the color filters CF1, CF2, and CF3 may be different from each other. The relative area ratio of the color filters CF1, CF2, and CF3 may affect the color of the reflected external light in case that the external light is reflected on the display device 1000. In the display device 1000, the color filters CF1, CF2, and CF3 have a specific ratio of area, and include the color pattern CP including the same material as the red color filter, so that the color of external light may have a color comfortable to the user's eyes. The disposition of the color filters CF1, CF2, and CF3 may be variously changed. For example, the color filters CF1, CF2, and CF3 may be disposed as a PenTile™ type or a diamond PenTile™ type.

The display device 1000 may include the light blocking member BM disposed between the light emitting areas EA1, EA2, and EA3 and the color filters CF1, CF2, and CF3. The light blocking member BM may include the light blocking member openings OPT1, OPT2, and OPT3. The light blocking member openings OPT1, OPT2, and OPT3 may overlap the pixel openings OPE1, OPE2, and OPE3 of the pixel defining layer BPDL corresponding to the light emitting areas EA1, EA2, and EA3, and may form a light emitting area where light emitted from the light emitting areas EA1, EA2, and EA3 is emitted. Each of the color filters CF1, CF2, and CF3 may have a larger area than the corresponding light blocking member openings OPT1, OPT2, and OPT3 of the light blocking member BM and the corresponding pixel openings OPE1, OPE2, and OPE3 of the pixel defining layer BPDL, and may cover (e.g., completely cover) the corresponding light emitting area.

The pixel openings OPE1, OPE2, and OPE3 and the light blocking member openings OPT1, OPT2, and OPT3 may have a circular planar shape. The light reflected by the circular planar shape may not be reflected in a specific direction, thereby preventing the reflected light from being concentrated in a specific direction, and preventing the reflected light from being readily visible.

Referring to the cross-sectional structure of the display area of FIG. 6, a buffer layer BF may be disposed on a substrate SUB. The substrate SUB may include a material having a rigid characteristic, such as glass, or a flexible material that is bendable, such as plastic and polyimide. The buffer layer BF may flatten the surface of the substrate SUB and block the penetration of impure elements. The buffer layer BF may include an inorganic material, for example, an inorganic insulation material such as silicon nitride (SiNₓ), silicon oxide (SiOₓ), or silicon oxynitride (SiOₓN_{y}). In some embodiments, the buffer layer BF may have a single-layered structure or a multi-layered structure including one or more inorganic insulating materials.

A semiconductor layer ACT may be disposed on the substrate SUB. The semiconductor layer ACT may include one of amorphous silicon, polycrystalline silicon, and an oxide semiconductor. For example, the semiconductor layer ACT may include a low-temperature polycrystalline silicon (LTPS), or may include an oxide semiconductor including at least one of zinc (Zn), indium (In), gallium (Ga), tin (Sn), and a mixture thereof. For example, the semiconductor layer ACT may include indium-gallium-zinc oxide (IGZO). The semiconductor layer ACT may include a channel region C, a source region S, and a drain region D, which are distinguished according to whether or not impurities are doped. The source region S and the drain region D may have conductive characteristics corresponding to a conductor.

A first gate insulating film GI1 may be disposed on the semiconductor layer ACT. The first gate insulating film GI1 may cover the semiconductor layer ACT and the substrate SUB. The first gate insulating film GI1 may include an inorganic insulating material such as silicon nitride (SiNₓ), silicon oxide (SiOₓ), and silicon oxynitride (SiOₓN_{y}). The first gate insulating film GI1 may have a single-layered structure or a multi-layered structure including one or more inorganic insulating materials.

A gate electrode GE1 may be disposed on the first gate insulating film GI1. The gate electrode GE1 may include a metal such as copper (Cu), molybdenum (Mo), aluminum (Al), silver (Ag), chromium (Cr), tantalum (Ta), and titanium (Ti), or a metal alloy thereof. The gate electrode GE1 may have a single-layered structure or a multi-layered structure. A region of the semiconductor layer ACT overlapping the gate electrode GE1 in a plan view may be the channel region C.

A second gate insulating film GI2 may be disposed on the gate electrode GE1. The second gate insulating film GI2 may include an inorganic insulating material such as silicon nitride (SiNₓ), silicon oxide (SiOₓ), and silicon oxynitride (SiOₓN_{y}). The second gate insulating film GI2 may have a single-layered structure or a multi-layered structure including one or more inorganic insulating materials.

A capacitor electrode GE2 may be disposed on the second gate insulating film GI2. The capacitor electrode GE2 may overlap the gate electrode GE1 and may form a capacitor.

A first insulating film IL1 may be disposed on the capacitor electrode GE2. The first insulating film IL1 may include an inorganic insulating material such as silicon nitride (SiNₓ), silicon oxide (SiOₓ), and silicon oxynitride (SiOₓN_{y}). The first insulating film IL1 may have a single-layered structure or a multi-layered structure including one or more inorganic insulating materials.

A source electrode SE and a drain electrode DE may be disposed on the first insulating film IL1. The source electrode SE and the drain electrode DE may be connected to the source region S and the drain region D of the semiconductor layer ACT by openings formed in the first insulating film IL1, the second gate insulating film GI2, and the first gate insulating film GI1, respectively. Accordingly, the semiconductor layer ACT, the gate electrode GE, the source electrode SE, and the drain electrode DE described above form one transistor. In some embodiments, the transistor may include only the source region and the drain region of the semiconductor layer ACT instead of the source electrode SE and the drain electrode DE. The source electrode SE and the drain electrode DE may include a metal such as aluminum (Al), copper (Cu), silver (Ag), gold (Au), platinum (Pt), palladium (Pd), nickel (Ni), molybdenum (Mo), tungsten (W), titanium (Ti), chromium (Cr), and tantalum (Ta), or a metal alloy thereof. The source electrode SE and the drain electrode DE may be formed as a single-layer structure or a multilayer structure. In some embodiments, the source electrode SE and the drain electrode DE may be formed of a triple layer including an upper layer, a middle layer, and a lower layer, and the upper layer and the lower layer may include titanium (Ti), and the middle layer may include aluminum (Al).

A second insulating film IL2 may be disposed on the source electrode SE and the drain electrode DE. The second insulating film IL2 may cover the source electrode SE and the drain electrode DE. The second insulating film IL2 may be for planarizing the surface of the substrate SUB provided with the transistor, and may be an organic insulating film, and may include one or more materials selected from the group consisting of polyimide, polyamide, an acrylic resin, benzocyclobutene, and a phenol resin.

A first electrode E1 may be disposed on the second insulating film IL2. The first electrode E1 may be also referred to as an anode electrode, and may be formed as a single-layer structure or a multilayer structure that includes a transparent conductive oxide film or a metal material. The transparent conductive oxide film may include indium tin oxide (ITO), a poly-ITO, indium zinc oxide (IZO), indium gallium zinc oxide (IGZO), and indium tin zinc oxide (ITZO). The metallic material may include silver (Ag), molybdenum (Mo), copper (Cu), gold (Au), aluminum (Al), and the like. The first electrode E1 may be physically and electrically connected to the drain electrode DE through the pixel opening of the second insulating film IL2. Accordingly, the first electrode E1 may receive an output current to be transmitted from the drain electrode DE to the light emitting layer EML.

A pixel defining layer BPDL and a spacer SPC may be disposed on the first electrode E1 and the second insulating film IL2. The pixel defining layer BPDL may include a pixel opening OPE1 and may overlap at least a portion of the first electrode E1. For example, the pixel opening OPE1 may overlap a central portion of the first electrode E1, and may not overlap an edge portion of the first electrode E1. Accordingly, a size of the pixel opening OPE1 may be smaller than that of the first electrode E1. The pixel defining layer BPDL may partition the formation position of the light emitting layer EML so that the light emitting layer EML may be disposed on a portion in which the upper surface of the first electrode E1 is exposed. Each of the pixel defining layer BPDL and the spacer SPC may be an organic insulating film including one or more materials selected from the group consisting of polyimide, polyamide, an acrylic resin, benzocyclobutene, and a phenol resin. The pixel defining layer BPDL may include a black pigment.

The light emitting layer EML may be disposed in the pixel opening OPE1 partitioned by the pixel defining layer BPDL. The light emitting layer EML may include an organic material that emits red, green, and blue light. The light emitting layer EML emitting red, green, and blue light may include low-molecular-weight organic materials or high-molecular-weight organic materials. In FIG. 6, the light emitting layer EML is illustrated as a single layer, but in reality, auxiliary layers such as an electron injection layer, an electron transport layer, a hole transport layer, and a hole injection layer may also be included above and below the light emitting layer EML, and the hole injection layer and the hole transport layer may be disposed below the light emitting layer EML, and the electron transport layer and the electron injection layer may be disposed above the light emitting layer EML. In some embodiments, the light emitting layer EML may include quantum dots. The quantum dots (hereinafter also referred to as semiconductor nanocrystals) may include a group II-VI compound, a group III-V compound, a group IV-VI compound, a group IV element or compound, a group I-III-VI compound, a group II-III-VI compound, a group I-II-IV-VI compound, or a combination thereof. The quantum dots may not include cadmium.

A second electrode E2 may be disposed on the pixel defining layer BPDL and the light emitting layer EML. The second electrode E2 is also referred to as a cathode, and may be formed of a transparent conductive layer including indium tin oxide (ITO), indium zinc oxide (IZO), indium gallium zinc oxide (IGZO), and indium tin zinc oxide (ITZO). For example, the second electrode E2 may have a translucent characteristic, and may form a micro-cavity together with the first electrode E1. According to the structure of the micro-cavity, light with a specific wavelength may be emitted upward by a gap and characteristic between electrodes at end portions (e.g., opposite end portions) thereof, and red, green, or blue colors may be displayed.

The first electrode E1, the light emitting layer EML, and the second electrode E2 may form one light emitting element ED.

An encapsulation layer ENC may be disposed on the second electrode E2. The encapsulation layer ENC may include at least one inorganic layer and at least one organic layer. In an embodiment, the encapsulation layer ENC may include a first inorganic encapsulation layer EIL1, an organic encapsulation layer EOL, and a second inorganic encapsulation layer EIL2. However, this is only an example, and the number of inorganic and organic films configuring the encapsulation layer ENC may be variously changed.

A light blocking member BM and color filters CF1, CF2, and CF3 may be disposed on the encapsulation layer ENC. The light blocking member BM may overlap the pixel defining layer BPDL, and may be spaced apart from the light emitting layer EML without overlapping the light emitting layer EML. The light blocking member BM may include light blocking member openings OPT1, OPT2, and OPT3 as shown in FIG. 5. The color filters CF1, CF2, and CF3 may be disposed between the light blocking members BM, and the color filters CF1, CF2, and CF3 may be disposed in the light blocking member openings OPT1, OPT2, and OPT3. Referring to FIG. 5 and FIG. 6, the sizes of the light blocking member openings OPT1, OPT2, and OPT3 may be larger than the sizes of the pixel openings OPE1, OPE2, and OPE3, and the pixel openings OPE1, OPE2, and OPE3 may overlap the light blocking member openings OPT1, OPT2, and OPT3.

A planarization layer OC covering the color filters CF1, CF2, and CF3 may be disposed on the color filters CF1, CF2, and CF3. The planarization layer OC may be for planarizing the upper surface of the light emitting display panel, and may be a transparent organic insulating film including one or more materials selected from the group consisting of polyimide, polyamide, an acrylic resin, benzocyclobutene, and a phenol resin.

The pixel defining layer BPDL may include an upper surface FP and a side surface TP connected to the upper surface FP. The side surface TP may be connected to the upper surface FP at an edge portion of the upper surface FP. The upper surface FP of the pixel defining layer BPDL may be a surface parallel to the upper surface of the first electrode E1, and the side surface TP may be inclined with respect to the upper surface of the first electrode E1. The upper surface FP and the side surface TP of the pixel defining layer BPDL may be formed using a slit mask. A photosensitive film pattern having different thicknesses for each area may be formed using the slit mask, and the upper surface FP and the side surface TP may be formed by etching the pixel defining layer BPDL.

Referring to FIG. 5 and FIG. 6, the upper surface FP of the pixel defining layer BPDL may overlap the light blocking member BM in a plan view, and for example, the entire upper surface FP of the pixel defining layer BPDL may overlap the light blocking member BM. At least a portion of the side surface TP of the pixel defining layer BPDL may overlap the light blocking member openings OPT1, OPT2, and OPT3.

An edge portion of the upper surface FP of the pixel defining layer BPDL, e.g., a line on which the upper surface FP and the side surface TP may be in contact with each other, and is referred to as a contact line P. The contact line P may overlap the light blocking member BM. For example, the entire contact line P may overlap the light blocking member BM. The size of the upper surface FP of the pixel defining layer BPDL may be smaller than the size of the light blocking member BM.

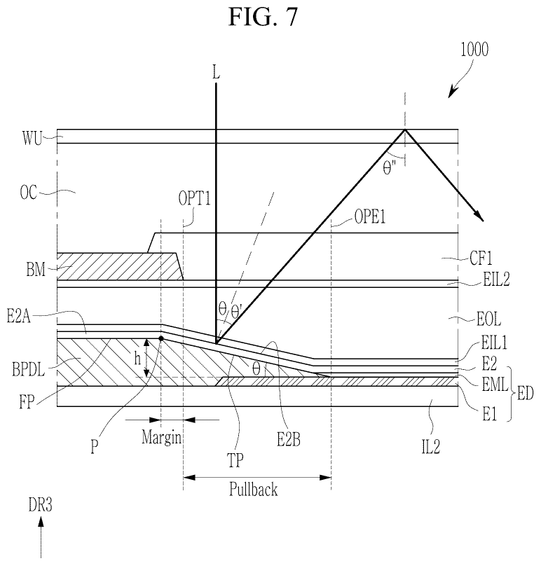

Hereinafter, a structure of a pixel defining layer BPDL and a light blocking member BM in a display area of a display device according to an embodiment will be described with reference to FIG. 7 together with FIG. 5 and FIG. 6. FIG. 7 illustrates a schematic cross-sectional view of a portion of a display area shown in FIG. 6.

Referring to FIG. 7, the pixel defining layer BPDL may include an upper surface FP and a side surface TP connected to the upper surface FP. The side surface TP may be connected to the upper surface FP at an edge portion of the upper surface FP. The upper surface FP of the pixel defining layer BPDL may be a surface parallel to the upper surface of the first electrode E1, and the side surface TP may be inclined with respect to the upper surface of the first electrode E1. The upper surface FP of the pixel defining layer BPDL may overlap the light blocking member BM in a plan view. For example, the entire upper surface FP of the pixel defining layer BPDL may overlap the light blocking member BM. The size of the upper surface FP of the pixel defining layer BPDL may be smaller than the size of the light blocking member BM. At least a portion of the side surface TP of the pixel defining layer BPDL may overlap the light blocking member opening OPT1. An edge portion of the upper surface FP of the pixel defining layer BPDL, e.g., a line on which the upper surface FP and the side surface TP are in contact with each other, and is referred to as a contact line P. The contact line P may overlap the light blocking member BM. For example, the entire contact line P may overlap the light blocking member BM. The second electrode E2 may include a first area E2A which is in contact with the upper surface FP of the pixel defining layer BPDL and a second area E2B which is not in contact with the upper surface FP of the pixel defining layer BPDL. External light L entering the display area may not be reflected from the upper surface of the first area E2A of the second electrode E2, but may be reflected from the upper surface of the second area E2B of the second electrode E2.

Referring to FIG. 5 and FIG. 7, the minimum planar distance between the edge portion of the light blocking member BM and the edge portion of the side TP of the pixel defining layer BPDL is referred to as a separation distance (Pullback). The minimum planar distance between the edge portion of the light blocking member BM and the edge portion of the upper surface FP of the pixel defining layer BPDL is referred to as a margin distance (Margin). An angle formed by the side surface TP of the pixel defining layer BPDL and the upper surface of the first electrode E1 in a cross-sectional view is referred to as an inclination angle (θ). The inclination angle (θ) may be greater than 0° and less than 90°. A distance between the upper surface FP of the pixel defining layer BPDL and the upper surface of the first electrode E1 in the third direction DR3 is referred to as a thickness (h). For example, the relationship between the separation distance (Pullback), the margin distance (Margin), the inclination angle (θ), and the thickness (h) is as follows.

$$tan θ = \frac{h}{Pullback + Margin}$$

Here, the reflection angle (θ′) in case that the external light L incident from the third direction DR3 is reflected from the inclined surface TP may be substantially the same as the inclination angle (θ). An incident angle (θ″) in case that the external light L reflected from the inclined surface TP is reflected from the surface of the cover window WU may be about twice the inclination angle (θ).

The margin distance (Margin) may be greater than 0 and less than or equal to about 2 μm, for example, about 1 μm. The separation distance (Pullback) may be about 4 μm to about 6 μm, for example, about 5 μm. For example, the thickness (h) may be about 2 μm to about 4 μm, for example, about 2.24 μm to about 3.46 μm. The inclination angle (θ) may be about 20.5° to about 30°. For example, the inclination angle (θ) may be about 20.5° and the thickness (h) may be about 2.24 μm. In some embodiments, the inclination angle (θ) may be about 30° and the thickness (h) may be about 3.46 μm.

The refractive index of the cover window WU may be about 1.5. For example, in case that the inclination angle (θ) and the reflection angle (θ′) is about 20.5° or more, e.g., the incident angle (θ″) is about 41° or more. The external light L reflected from the upper surface of the second area E2B of the second electrode E2 may be reflected (e.g., totally reflected) on the surface of the cover window WU. For example, the external light L entering the display area may not be emitted to the outside, but may be reflected (e.g., totally reflected) back to the inside to cause a substrate mode to occur. Accordingly, external light reflection may be reduced, and the reflection diffraction pattern caused by external light reflection may be reduced, so visibility may be improved.

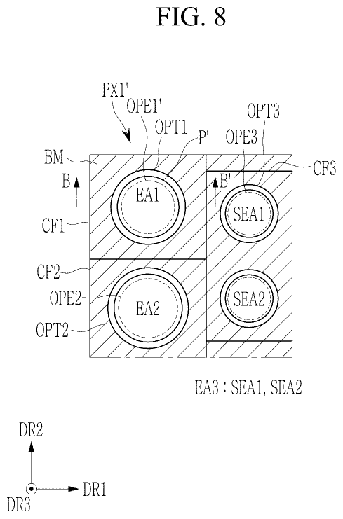

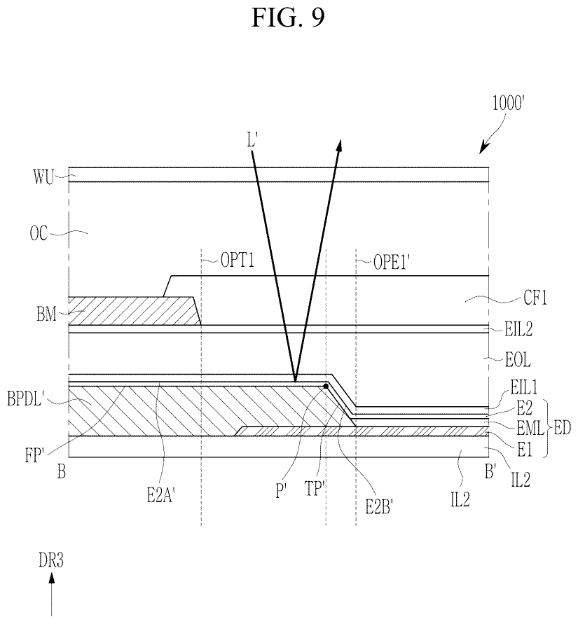

Hereinafter, a structure of a unit pixel in a display area of a display device 1000′ according to a comparative example will be described with reference to FIG. 8 and FIG. 9. FIG. 8 is a schematic plan view of a shape of a unit pixel PX1′ of a display device according to a comparative example, and FIG. 9 is a schematic cross-sectional view taken along line B-B′ of FIG. 8.

Referring to FIG. 8, in a display device 1000′ according to a comparative example, each of the light emitting areas EA1, EA2, and EA3 may be defined by pixel openings OPE1′, OPE2′, and OPE3′ formed in a pixel defining layer BPDL′ of a light emitting element ED. The display device 1000′ according to the comparative example may include color filters CF1, CF2, and CF3 disposed on the light emitting areas EA1, EA2, and EA3. The display device 1000′ may include a light blocking member BM disposed between the light emitting areas EA1, EA2, and EA3 and the color filters CF1, CF2, and CF3. The light blocking member BM may include light blocking member openings OPT1, OPT2, and OPT3. The light blocking member openings OPT1, OPT2, and OPT3 may overlap the pixel openings OPE1′, OPE2′, and OPE3′ of the pixel defining layer BPDL′ corresponding to the light emitting areas EA1, EA2 and EA3.

Referring to the cross-sectional structure of the display area of the display device according to the comparative example with reference to FIG. 9, the pixel defining layer BPDL′ may be disposed on the first electrode E1 and the second insulating film IL2. The pixel defining layer BPDL′ may include a pixel opening OPE1′ and overlap at least a portion of the first electrode E1. The light emitting layer EML may be disposed in the pixel opening OPE1′ partitioned by the pixel defining layer BPDL′.

The pixel defining layer BPDL′ may include an upper surface FP′ and a side surface TP′ connected to the upper surface FP′. The side surface TP′ may be connected to the upper surface FP′ at an edge portion of the upper surface FP′. The upper surface FP′ of the pixel defining layer BPDL′ may be a surface parallel to the upper surface of the first electrode E1, and the side surface TP′ may be inclined with respect to the upper surface of the first electrode E1. The second electrode E2 may include a first area E2A′ which is in contact with the upper surface FP′ of the pixel defining layer BPDL′ and a second area E2B′ which is not in contact with the upper surface FP′ of the pixel defining layer BPDL′.

Referring to FIG. 8 and FIG. 9, in the comparative example, a contact line P′, at which the upper surface FP′ and the side surface TP′ of the pixel defining layer BPDL′ meet, may not overlap the light blocking member BM, and may be spaced apart from the light blocking member BM. The size of the upper surface FP′ of the pixel defining layer BPDL′ may be larger than the size of the light blocking member BM. In a plan view, the upper surface FP′ of the pixel defining layer BPDL′ may overlap the light blocking member opening OPT1. Accordingly, an external light L′ entering the display area may also be reflected from the upper surface of the first area E2A′ of the second electrode E2. The external light L′ reflected from the upper surface of the first area E2A′ of the second electrode E2 may be emitted to the outside without causing total reflection on the surface of the cover window WU. Accordingly, a reflective diffraction pattern due to external light reflection may be recognized.

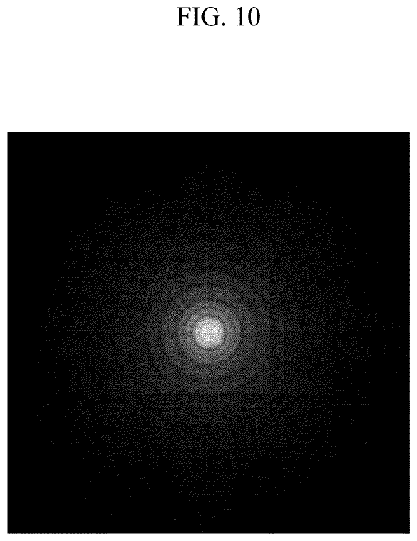

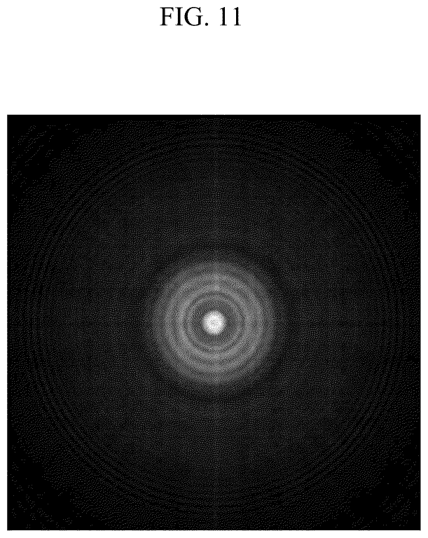

Hereinafter, reflection characteristics of a display device according to an embodiment and a display device according to a comparative example will be described with reference to FIG. 10 and FIG. 11.

FIG. 10 is an image of reflection characteristics of the display device according to an embodiment shown in FIG. 5 to FIG. 7. Referring to FIG. 10, it can be seen that a reflective diffraction pattern is hardly visible in the display device according to an embodiment.

FIG. 11 is an image of reflection characteristics of the display device according to the comparative example shown in FIG. 8 and FIG. 9. Referring to FIG. 11, it can be seen that a halo occurring around strong light is visually recognized in the display device according to the comparative example. A halo recognized in the display device according to the comparative example is larger than in the display device according to an embodiment of the present disclosure.

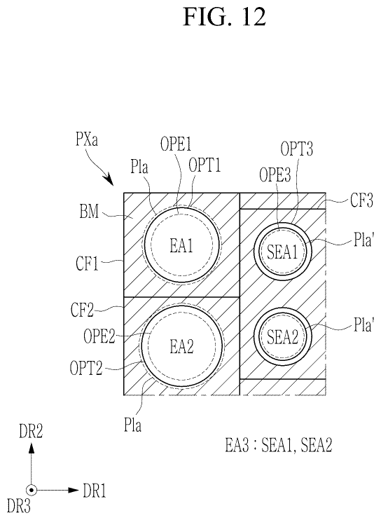

Hereinafter, a shape of a display area of a display device according to another embodiment will be described with reference to FIG. 12 to FIG. 14. FIG. 12 to FIG. 14 are schematic plan views of unit pixels PXa, PXb, and PXc in a display area of a display device according to another embodiment.

FIG. 12 illustrates the unit pixel PXa having a shape of the pixel defining layer of the third light emitting area EA3 that is different from the first and second light emitting areas EA1 and EA2. Referring to FIG. 12, the first light emitting area EA1 and the second light emitting area EA2 may include the pixel defining layer BPDL of the display device according to an embodiment shown in FIG. 5 to FIG. 7. The third light emitting area EA3 may include the pixel defining layer BPDL′ of the display device according to the comparative example shown in FIG. 8 and FIG. 9.

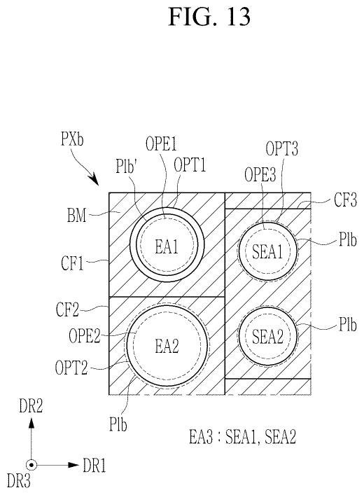

FIG. 13 illustrates the unit pixel PXb having a shape of the pixel defining layer of the first light emitting area EA1 that is different from the second and third light emitting areas EA2 and EA3. Referring to FIG. 13, the second light emitting area EA2 and the third light emitting area EA3 may include the pixel defining layer BPDL of the display device according to an embodiment shown in FIG. 5 to FIG. 7. The first light emitting area EA1 may include the pixel defining layer BPDL′ of the display device according to the comparative example shown in FIG. 8 and FIG. 9.

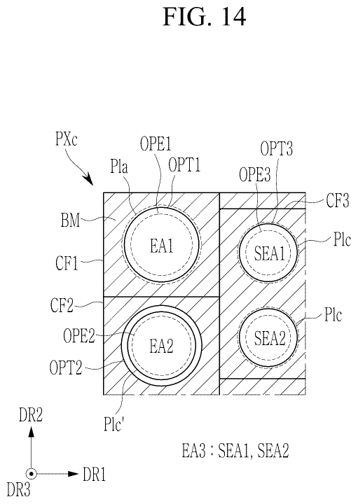

FIG. 14 illustrates the unit pixel PXc having a shape of the pixel defining layer of the second light emitting area EA2 that is different from the first and third light emitting areas EA1 and EA3. Referring to FIG. 14, the first light emitting area EA1 and the third light emitting area EA3 may include the pixel defining layer BPDL of the display device according to an embodiment shown in FIG. 5 to FIG. 7. The second light emitting area EA2 may include the pixel defining layer BPDL′ of the display device according to the comparative example shown in FIG. 8 and FIG. 9.

Referring to FIG. 12 to FIG. 14, in the display device according to another embodiment, the distribution of color may be controlled by having a difference in the shape of the pixel defining layer BPDL and BPDL′ of at least some of the light emitting areas EA1, EA2, and EA3.

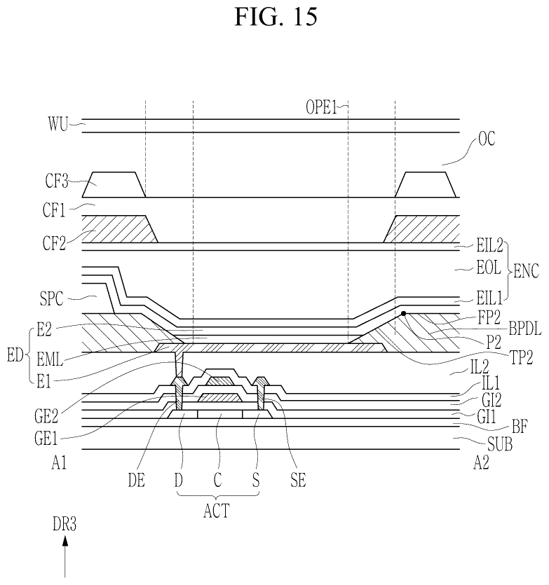

Hereinafter, a shape of a display area of a display device according to another embodiment will be described with reference to FIG. 15. FIG. 15 is a schematic cross-sectional view of a structure of a display area of a display device according to another embodiment.

Referring to FIG. 15, the color filters CF1, CF2, and CF3 may be disposed on the encapsulation layer ENC. For example, the second color filter CF2 and the third color filter CF3 may overlap the pixel defining layer BPDL and may be spaced apart from the light emitting layer EML without overlapping it. The first color filter CF1 may be disposed to overlap the pixel defining layer BPDL and the first electrode E1. For example, the first pixel opening OPEL may overlap the first color filter CF1, and may be spaced apart from the second color filter CF2 and the third color filter CF3 without overlapping them. In some embodiments, the first color filter CF1 and the second color filter CF2 may overlap the pixel defining layer BPDL and may be spaced apart from the light emitting layer EML without overlapping the light emitting layer EML. The third color filter CF3 may be disposed to overlap both the pixel defining layer BPDL and the first electrode E1. For example, the third pixel opening OPE3 may overlap the third color filter CF3, and may be spaced apart from the first color filter CF1 and the second color filter CF2 without overlapping them. In some embodiments, the first color filter CF1 and the third color filter CF3 may overlap the pixel defining layer BPDL and may be spaced apart from the light emitting layer EML without overlapping the light emitting layer EML. The second color filter CF2 may be disposed to overlap both the pixel defining layer BPDL and the first electrode E1. For example, the second pixel opening OPE2 may overlap the second color filter CF2, and may be spaced apart from the first color filter CF1 and the third color filter CF3 without overlapping them.

In case that the second color filter CF2 and the third color filter CF3 overlap the pixel defining layer BPDL and are spaced apart from the light emitting layer EML and the first color filter CF1 is disposed to overlap both the pixel defining layer BPDL and the first electrode E1, the positional relationship between the upper surface FP2 and the side surface TP2 of the pixel defining layer BPDL is as follows. The entire contact line P2 at which the upper surface FP2 and the side surface TP2 of the pixel defining layer BPDL meet may overlap the first color filter CF1, the second color filter CF2, and the third color filter CF3 along the third direction DR3 in a cross-sectional view. The upper surface FP2 of the pixel defining layer BPDL may overlap the first color filter CF1, the second color filter CF2, and the third color filter CF3 along the third direction DR3 in a cross-sectional view. For example, the entire upper surface FP2 of the pixel defining layer BPDL may overlap the first color filter CF1, the second color filter CF2, and the third color filter CF3. The edge portion of the side surface TP2 of the pixel defining layer may overlap the first color filter CF1 in a plan view, and may be spaced apart from the second color filter CF2 and the third color filter CF3 without overlapping them.

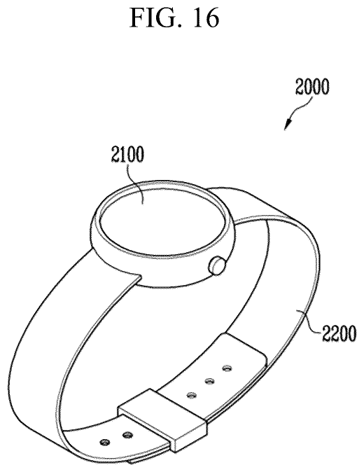

Referring to FIG. 16, the electronic device may be applied to a smart watch 2000 including a display part 2100 and a strap part 2200.

The smart watch 2000 may be a wearable electronic device. For example, the smart watch 2000 may have a structure in which the strap part 2200 is mounted on a wrist of a user. The electronic device may be applied to the display part 2100, so that image data including time information can be provided to the user.

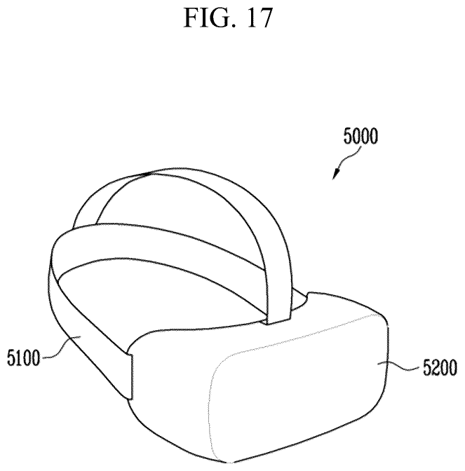

Referring to FIG. 17, the electronic device may be applied to a head mounted display device 5000.

The head mounted display device 5000 may be a wearable electronic device which can be worn on the head of a user. For example, the head mounted display device 5000 may be a wearable device for virtual reality (VR) or mixed reality (MR). The head mounted display device 5000 may include a head mounted band 5100 and a display accommodating case 5200. The head mounted band 5100 may be connected to the display accommodating case 5200. The head mounted band 5100 may include a horizontal band and/or a vertical band, used to fix the head mounted display device 5000 to the head of the user. The horizontal band may be formed to surround a side portion of the head of the user, and the vertical band may be formed to surround an upper portion of the head of the user. However, embodiments are not limited thereto. For example, the head mounted band 5100 may be implemented in the form of a glasses frame, a helmet or the like within the spirit and the scope of the disclosure.

For example, the electronic device may be at least one of televisions, notebook computers, monitors, advertisement boards, Internet of things (IoTs), portable electronic apparatuses including mobile phones, smartphones, tablet personal computers (PCs), mobile communication terminals, electronic organizers, electronic books, portable multimedia players (PMPs), navigations, ultra mobile personal computers (UMPCs), smartwatches, watchphones, glasses-type displays, head-mounted displays (HMDs), instrument panels for automobiles, center fascias for automobiles, or center information displays (CIDs) on a dashboard, room mirror displays of automobiles, and displays of an entertainment system on a backside of front seats in automobiles.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a substrate;
a first electrode disposed on the substrate;
a pixel defining layer having a pixel opening disposed on the first electrode;
a light emitting layer disposed in the pixel opening;
a second electrode disposed on the light emitting layer;
an encapsulation layer disposed on the second electrode; and
a light blocking member disposed on the encapsulation layer, overlapping the pixel defining layer, and having a light blocking member opening, wherein
an entire upper surface of the pixel defining layer overlaps the light blocking member, and
at least a portion of a side surface of the pixel defining layer overlaps the light blocking member opening.

2. The display device of claim 1, wherein
a contact line where the upper surface and the side surface of the pixel defining layer meet overlaps the light blocking member.

3. The display device of claim 1, wherein
at least a portion of the side surface of the pixel defining layer overlaps the light blocking member.

4. The display device of claim 1, wherein
a separation distance (Pullback) that is a minimum planar distance between an edge portion of the side surface of the pixel defining layer and an edge portion of the light blocking member, a margin distance (Margin) that is a minimum planar distance between an edge portion of the upper surface of the pixel defining layer and an edge portion of the light blocking member, an inclination angle (θ) that is an angle formed by the side surface of the pixel defining layer and the upper surface of the first electrode, and a thickness (h) that is a vertical distance in a cross-sectional view between the upper surface of the pixel defining layer and the upper surface of the first electrode are in a relationship as follows.
$$tan θ = \frac{h}{Pullback + Margin}$$

5. The display device of claim 4, wherein
the separation distance is in a range of about 4 μm to about 6 μm, and
the margin distance is greater than about 0 and less than or equal to about 2 μm.

6. The display device of claim 5, wherein
the inclination angle is in a range of about 20.5° to about 30°.

7. The display device of claim 5, wherein
the thickness is in a range of about 2 μm to about 4 μm.

8. The display device of claim 1, further comprising
a color filter disposed between adjacent light blocking members.

9. The display device of claim 8, further comprising
a cover window disposed on the light blocking member and the color filter.

10. A display device comprising:
a substrate;
a first electrode disposed on the substrate;
a first pixel defining layer having a first pixel opening and a second pixel defining layer having a second pixel opening, wherein the first pixel opening and the second pixel opening are disposed on the first electrode;
a first light emitting layer disposed in the first pixel opening;
a second light emitting layer disposed in the second pixel opening;
a second electrode disposed on the first light emitting layer and the second light emitting layer;
an encapsulation layer disposed on the second electrode; and
a light blocking member disposed on the encapsulation layer, overlapping the first pixel defining layer and the second pixel defining layer, and having a light blocking member opening, wherein
the first pixel defining layer includes a first upper surface and a first side surface,
the entire first upper surface overlaps the light blocking member and at least a portion of the first side surface overlaps the light blocking member opening,
the second pixel defining layer includes a second upper surface and a second side surface, and
at least a portion of the second upper surface overlaps the light blocking member opening.

11. The display device of claim 10, wherein
the second side surface of the second pixel defining layer is spaced apart from the light blocking member in a plan view.

12. The display device of claim 10, wherein
a first contact line where the first upper surface and the first side surface meet overlaps the light blocking member, and
a second contact line where the second upper surface and the second side surface meet overlaps the light blocking member opening.

13. The display device of claim 10, wherein
the first light emitting layer and the second light emitting layer emit light of different colors.

14. An electronic device comprising:
a display device comprising:
a substrate;
a first electrode disposed on the substrate;
a pixel defining layer having a pixel opening disposed on the first electrode;
a light emitting layer disposed in the pixel opening;
a second electrode disposed on the light emitting layer;
an encapsulation layer disposed on the second electrode; and
a light blocking member disposed on the encapsulation layer, overlapping the pixel defining layer, and having a light blocking member opening, wherein
an entire upper surface of the pixel defining layer overlaps the light blocking member, and
at least a portion of a side surface of the pixel defining layer overlaps the light blocking member opening.

15. The electronic device of claim 14, wherein
a contact line where the upper surface and the side surface of the pixel defining layer meet overlaps the light blocking member.

16. The electronic device of claim 14, wherein
at least a portion of the side surface of the pixel defining layer overlaps the light blocking member.

17. The electronic device of claim 14, wherein
a separation distance (Pullback) that is a minimum planar distance between an edge portion of the side surface of the pixel defining layer and an edge portion of the light blocking member, a margin distance (Margin) that is a minimum planar distance between an edge portion of the upper surface of the pixel defining layer and an edge portion of the light blocking member, an inclination angle (θ) that is an angle formed by the side surface of the pixel defining layer and the upper surface of the first electrode, and a thickness (h) that is a vertical distance in a cross-sectional view between the upper surface of the pixel defining layer and the upper surface of the first electrode are in a relationship as follows.
$$tan θ = \frac{h}{Pullback + Margin}$$

18. The electronic device of claim 17, wherein
the separation distance is in a range of about 4 μm to about 6 μm, and
the margin distance is greater than about 0 and less than or equal to about 2 μm.

19. The electronic device of claim 14, wherein the electronic device is at least one of an organic light-emitting display apparatus, an inorganic light-emitting display apparatus, a quantum dot light-emitting display apparatus, display screens of portable electronic apparatus, such as mobile phones, smartphones, tablet personal computers (PCs), mobile communication terminals, electronic notebooks, electronic books, portable multimedia players (PMPs), navigation devices, and ultra mobile PCs (UMPCs), display screens of televisions, notebooks, monitors, advertisement panels, Internet of things (IoT) devices, a portable communication device a smartphone, a computer device, a portable multimedia device, a portable medical device, a camera, a wearable device, and a home appliance.
